(19) United States
(12) Patent Application Publication
(10) Pub. No.: US 2025/0031357 A1
(43) Pub. Date: Jan. 23, 2025

(54) BONDING TOOL INCORPORATING DECOUPLED MOTION AXES

(71) Applicant: ASMPT Singapore Pte. Ltd., Singapore (SG)

(72) Inventors: Chi Wah CHENG, Hong Kong (CN); Wan Yin YAU, Hong Kong (CN); Hok Man WAN, Hong Kong (CN)

(21) Appl. No.: 18/223,594

(22) Filed: Jul. 19, 2023

(51) Int. Cl. H05K 13/04

(52) U.S. Cl. CPC H05K 13/0406

(57) ABSTRACT

A bonding tool with a decoupling mechanism includes a shaft, a rotary module coupled to a first portion of the shaft, a rotary motion actuator operatively connected to the rotary module and operative to drive the rotary module and the shaft to rotate about a rotary axis extending substantially along a central axis of the shaft, a linear motion module coupled to a second portion of the shaft separate from the first portion, and a linear motion actuator operatively connected to the linear motion module and operative to drive the linear motion module and the shaft to move in directions parallel to the rotary axis.

### FIELD OF THE INVENTION

The invention generally relates to a bonding tool for picking and placing an electronic component, e.g., a die, and exerting a bonding force to the electronic component during a bonding operation, and more specifically to a bonding tool or bond arm with a decoupling mechanism for decoupling a rotary motion axis and a linear motion axis of the bond arm.

### BACKGROUND

In an epoxy die bonding process, a bond arm as one of the core modules of a bonding tool is used to provide a force for picking and placing dies and adjusting rotational angular orientations of the picked dies. In order to realize the above functions, the bond arm is typically designed to have a rotary axis and a linear motion axis. In conventional bond arms, one of the two axes is arranged as a base axis and the other is installed on the base axis and moves on top of the base axis. With the coupling between the two axes, the load of a drive system for the rotary movement and linear movement of the bond arm will be increased, and the actuation and stop characteristics and the positioning accuracy of the bond arm will be greatly adversely affected. In order to decouple the coupling between the two axes, different bond arms have been proposed.

In one prior art bond arm, a timing belt is used to drive the rotary axis/shaft for the purpose of decoupling. However, as the timing belt is an indirect driving mechanism, there will be a latency before the rotary shaft is driven by the output of the rotary motor through the timing belt, which will cause an inconsistent bonding force. Further, a bending moment will occur during the application of a bonding force due to the non-symmetrical design of the bonding tool around the linear motion axis.

In another prior art bond arm, a set of gears is used to drive the rotary axis for the purpose of decoupling. However, the friction between gear teeth will cause an inconsistent bonding force. Further, clearances between gears may result in a rotational clearance of the rotary shaft of the bond arm. In addition, friction generated due to the use of a pneumatic cylinder for guiding the linear motion axis will also lead to inconsistency in the bonding force applied to the die.

It would therefore be beneficial to provide a new bond arm design with a decoupling mechanism, which can avoid at least one of the above-mentioned shortcomings in the prior art bond arms.

### SUMMARY OF THE INVENTION

It is thus an object of the invention to seek to provide an improved bonding tool or bond arm with a decoupling mechanism for decoupling a coupling between a rotary axis and a linear motion axis of the bonding tool.

According to various embodiments of the present invention, there is provided a bonding tool with a new decoupling mechanism. The bonding tool comprises a shaft, a rotary module coupled to a first portion of the shaft, a rotary motion actuator operatively connected to the rotary module and operative to drive the rotary module and the shaft to rotate about a rotary axis extending substantially along a central axis of the shaft, a linear motion module coupled to a second portion of the shaft separate from the first portion, and a linear motion actuator operatively connected to the linear motion module and operative to drive the linear motion module and the shaft to move in directions parallel to the rotary axis.

The bond arms proposed in various embodiments of the invention include separate rotary and linear motion modules which are respectively coupled to two separate portions of the shaft, and are driven by respective actuators or motors. Since the rotary movement and linear movement of the bond arm are actuated by respective direct driving mechanisms, inconsistent bonding force caused by any indirect driving mechanisms can be substantially avoided. With the proposed design, the linear motion module and the rotary module will not move together, the rotary and linear movements of the bond arm are therefore effectively decoupled, and position control of the bond arm will be greatly improved.

In some embodiments, the first portion of the shaft may be an upper portion of the shaft, and the second portion may be a lower portion of the shaft separate from the upper portion, i.e., the rotary module may be coupled to the upper portion of the shaft and the linear motion module may be coupled to the lower portion of the shaft. Alternatively, the first portion may be the lower portion of the shaft and the second portion may be the upper portion of the shaft, i.e., the rotary module may be coupled to the lower portion of the shaft, while the linear motion motor may be coupled to the upper portion of the shaft.

Preferably, the shaft may pass through both a central opening formed on the rotary module and a central opening formed on the linear motion module so that a connecting means for proving vacuum to the shaft for picking and transferring electronic components can be releasably and conveniently connected to the shaft. Alternatively, the shaft may not pass through or may only partially pass through the central opening formed on the rotary module or the linear motion module which is coupled to the upper portion of the shaft.

In order to reduce friction among different components during the rotary motion of the bonding tool, the bonding tool may further include a first rotary bearing coupled to the rotary module to guide the rotary module to rotate about the rotary axis, and a second rotary bearing coupled to the second portion of the shaft to guide the shaft to rotate about the rotary axis.

For reducing friction among different components during the linear motion of the bonding tool, the bonding tool may further include a first linear bearing coupled to the rotary module and the first portion of the shaft to guide the shaft to move in directions parallel to the rotary axis, and a second linear bearing coupled to the linear motion module to guide the linear motion module to move in directions parallel to the rotary axis.

In some embodiments, the first linear bearing may comprise a flexure or a ball spine. The first linear bearing is provided to transmit the rotary power from the rotary motion actuator to the shaft and to guide the linear motion of the shaft, i.e., provide freedom of motion in directions parallel to the rotary axis for the shaft to move up and down.

In some embodiments, the second linear bearing may include at least one flexure, a linear bush, a cage bearing or a ball spine, which is coupled to the linear motion module for guiding the linear motion module to move in directions parallel to the rotary axis. Preferably, the second linear bearing may include two flexures, one being coupled to a top portion of the linear motion module and the other one being coupled to a bottom portion of the linear motion module. The second linear bearing is provided to guide the linear motion of the linear motion module. As flexures function as non-contact type linear bearings, no friction is generated between the flexures and the linear motion module during the linear motion of the linear motion module, such that inconsistent bonding force caused by the friction between the linear motion module and the linear bearing(s) can be avoided.

So as to provide a more accurate bonding force, the linear motion actuator is designed to include at least two linear motion motors, e.g., electromagnetic motors or piezoelectric motors, which are arranged symmetrically around the shaft such that a total linear actuation force applied to the linear motion module is substantially collinear with a center of gravity of all linear moving parts of the bonding tool and a functional point of the bonding tool. With this collinear arrangement, a bending moment during the linear motion of the bonding tool is avoidable.

The bonding tool may further include an outer housing in which the rotary motion actuator and the linear motion actuator are fixedly installed. The outer housing is not moveable relative to other parts or components of the bonding tool. The outer housing may be designed to include a first housing portion and a second housing portion connected to each other. The first housing portion is configured for housing the rotary motion actuator, the rotary module and the first portion of the shaft, and the second housing portion is configured for housing the linear motion actuator, the linear motion module and the second portion of the shaft. Since the linear motion actuator is fixedly installed in the outer housing, it will not move together with the linear motion module, so that the moving mass of the linear motion axis is minimized, thereby achieving a smaller minimum bonding force and leading to more precise positioning of the bond arm as compared to prior art bond arms.

In order to monitor the linear motion of the shaft, the bonding tool may further include at least one linear encoder which is installed on the outer housing of the bonding tool and coupled to the linear motion module, a linear scale of the linear encoder being linearly movable with the linear motion module for determining a linear position of the shaft. To avoid inconsistent bonding force caused by an offset of the center of gravity of all linear moving parts from the center of the shaft, the bonding tool may be designed to include two similar or same linear encoders which are symmetrically arranged around the shaft.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1A is a schematic cross-sectional view of a bonding tool according to a first embodiment of the invention.

FIG. 1B to 1D respectively show horizontal cross-sectional views of the bonding tool along planes A-A′, B-B′ and C-C′ as indicated in FIG. 1A.

FIG. 1E is a schematic cross-sectional view of the bonding tool in FIG. 1A when the shaft of the bonding tool moves up parallel to a rotary axis according to the first embodiment.

FIG. 2 is a schematic cross-sectional view of a bonding tool according to a second embodiment of the invention.

FIG. 3 is a schematic cross-sectional view of a bonding tool according to a third embodiment of the invention.

FIG. 4 is a schematic cross-sectional view of a bonding tool according to a fourth embodiment of the invention.

FIG. 5A is a schematic cross-sectional view of a bonding tool according to a fifth embodiment of the invention; FIG. 5B to FIG. 5D respectively show perspective views of a ball spine, a cage bearing and a linear bush which can be used in the bonding tool in FIG. 5A.

FIG. 6A is a schematic cross-sectional view of a bonding tool according to a sixth embodiment of the invention; FIG. 6B is a perspective view of a linear motion guide according to the sixth embodiment.

FIG. 7 is a schematic cross-sectional view of a bonding tool according to a seventh embodiment of the invention.

FIG. 8 is a schematic cross-sectional view of a bonding tool according to an eighth embodiment of the invention.

In the drawings, like parts are denoted by like reference numerals.

### DETAILED DESCRIPTION OF THE PREFERRED EMBODIMENTS OF THE INVENTION

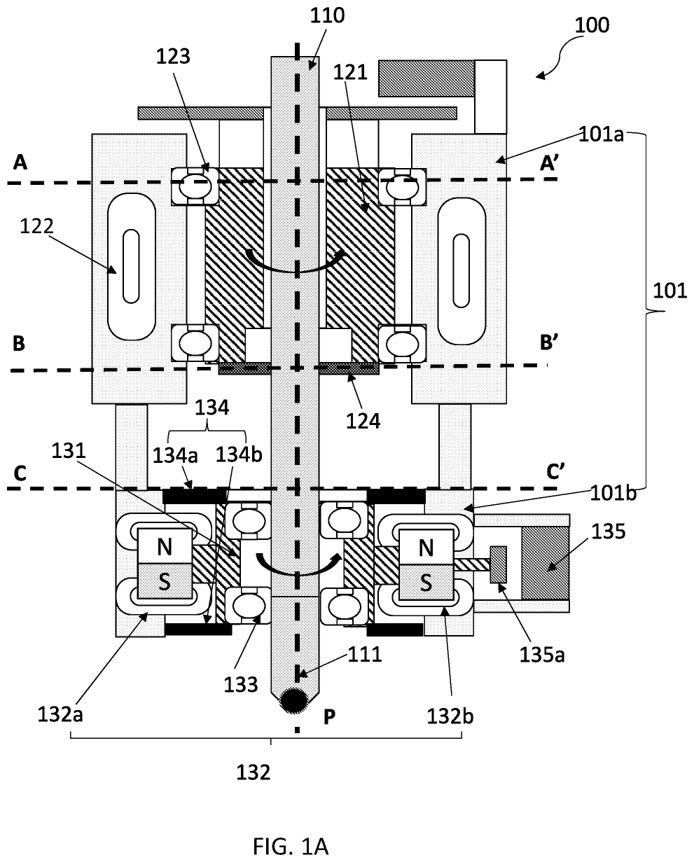

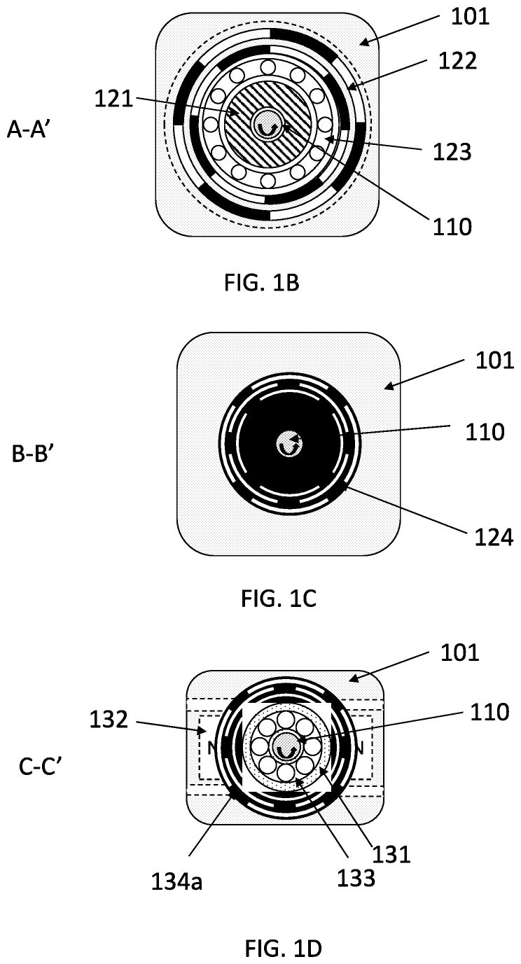

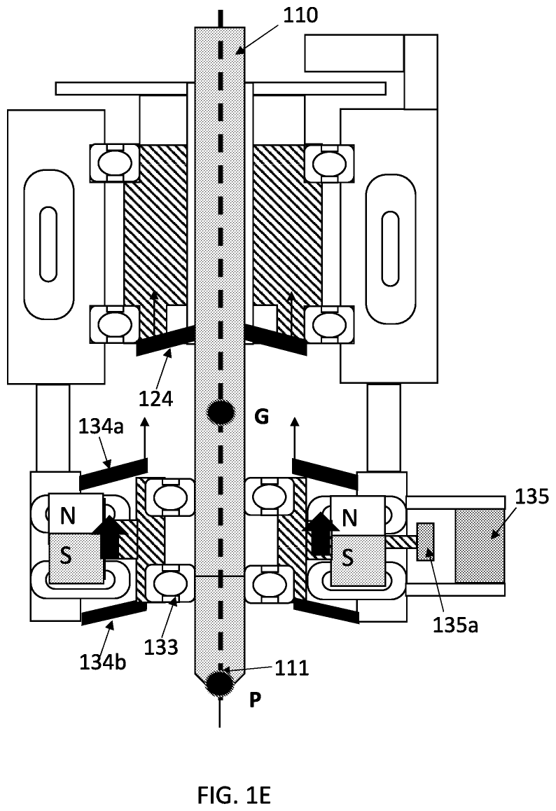

FIG. 1A is a schematic cross-sectional view of a bonding tool 100 according to a first embodiment of the invention. FIG. 1B to 1D respectively show horizontal cross-sectional views of the bonding tool 100 along the planes A-A′, B-B′ and C-C′ as indicated in FIG. 1A. Referring to FIG. 1A to FIG. 1D, the bonding tool 100 includes a shaft 110, a rotary module 121, a rotary motion actuator 122, a linear motion module 131 and a linear motion actuator 132.

A functional point or end-effector P of the bonding tool 100 is located at a bottom end of the shaft 110 for handling electronic components, e.g., picking and placing electronic components, adjusting rotational angles of the picked components and exerting a bonding force to the electronic components. As shown in FIG. 1A, the shaft 110 is configured to pass through both a central opening formed on the rotary module 121 and a central opening formed on the linear motion module 131 such that a connecting means (not shown), e.g., a pneumatic tube, can be releasably connected to the shaft 110 to provide a vacuum force to the shaft 110 for handling the electronic components via the functional point P. The rotary module 121 is coupled to an upper portion of the shaft 110 so that the shaft 110 is rotatable with the rotary module 121. The rotary motion actuator 122 is operably connected to the rotary module 121 and operative to drive the rotary module 121 and the shaft 110 to rotate about a rotary axis 111 extending substantially along a central axis of the shaft 110. The rotary motion actuator 122 is in the form of an electromagnetic rotary motor in this embodiment.

The linear motion module 131 is coupled to a lower portion of the shaft 110 so that the shaft 110 is movable with the linear motion module 131. The linear motion actuator 132 is operably connected to the linear motion module 131 and operative to drive the linear motion module 131 and the shaft 110 to move in directions parallel to the rotary axis 111, i.e., to move up and down parallel to the rotary axis 111. In this embodiment, the linear motion actuator 132 includes two electromagnetic motors 132a, 132b, which are symmetrically around the shaft 110.

The bonding tool 100 further includes a first rotary bearing 123 coupled to an external surface of the rotary module 121 to guide the rotary module 121 to rotate about the rotary axis 111, and a second rotary bearing 133 coupled to the lower portion of the shaft 110 to guide the shaft 110 to rotate about the rotary axis 111. The rotary bearings 123, 133 serve to reduce or avoid friction among different slidable components during the rotary motion of the bonding tool 100.

The bonding tool 100 further includes a first linear bearing 124 and a second linear bearing 134 in order to reduce or avoid friction among different components during the linear motion of the bonding tool 100. The first linear bearing 124 is configured to couple the rotary module 121 to an upper portion of the shaft 110 such that the rotary power generated from the rotary motion actuator 122 is transmitted to the shaft 110 such that the shaft 110 is driven to rotate together with the rotary module 121 about the rotary axis 111. In this embodiment, the first linear bearing 124 is in the form of a flexure. The second linear bearing 134 is coupled to the linear motion module 131 to guide the linear motion module 131 to move up and down parallel to the rotary axis 111. In this embodiment, the second linear bearing 134 includes a first flexure 134a coupled to a top portion of the linear motion module 131 and a second flexure 134b coupled to a bottom portion of the linear motion module 131. The second linear bearing 134 is provided to guide the linear motion of the linear motion module 131. The second flexure 134b of the second linear bearing 134 is also provided to support the linear motion module 131.

The bonding tool 100 further includes an outer housing 101 in which the rotary motion actuator 122 and the linear motion actuator 132 are fixedly installed. The outer housing 101 is not movable relative to other parts or components of the bonding tool 100. The outer housing 101 is designed to include an upper housing portion 101a and a lower housing portion 101b connected to each other. The upper housing portion 101a is configured to house the rotary motion actuator 122, the rotary module 121 and the upper portion of the shaft 110, and the lower housing portion 101b is configured to house the linear motion actuator 132, the linear motion module 131 and the lower portion of the shaft 110.

Referring to FIG. 1A, the bonding tool 100 further includes at least one encoder 135 to monitor the linear motion of the shaft 110. The encoder 135 is installed on the outer housing 101 of the bonding tool 100 and coupled to the linear motion module 131. A linear scale 135a of the linear encoder 135 is linearly movable with the linear motion module 131 for determining a linear position of the shaft 110.

FIG. 1E is a schematic cross-sectional view of the bonding tool 100 when the shaft 110 moves up in a direction parallel to the rotary axis 111 according to the first embodiment. The linear moving parts of the bonding tool 100 include the shaft 110, the first linear bearing 124, the linear motion module 131, the magnets of the two electromagnetic linear motors 132a, 132b of the linear motion actuator 132, the second rotary bearing 133, the first and second flexures 134a, 134b of the second linear bearing 134, and the scale 135a of the encoder 135. The substantially symmetrical design of the linear moving parts of the bonding tool 100 ensures that the center of gravity G of all linear moving parts is located at a point on the rotary axis 111. The symmetrical arrangement of the electromagnetic motors 132a, 132b ensures a similar force along a same direction parallel to the rotary axis 111 is applied to two sides of the linear motion module 131 by the two electromagnetic motors 132a, 132b. Thus, the shaft 110 will not be bent due to any bending moments when the shaft 110 is moving up or down parallel to the rotary axis.

It should be noted that the bonding tool 100 only includes one linear encoder 135 in this embodiment, however, in order to avoid inconsistent bonding forces caused by an offset of the center of gravity of all linear moving parts from the center axis of the shaft 110, the bonding tool 100 is more preferably designed to include two similar linear encoders which are symmetrically arranged around the shaft 110.

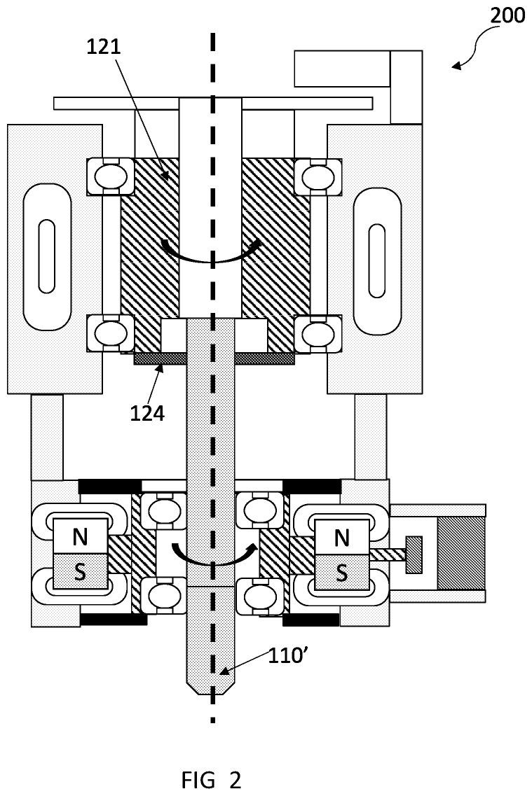

FIG. 2 is a schematic cross-sectional view of a bonding tool 200 according to a second embodiment of the invention. Compared with the bonding tool 100 of the first embodiment, the main difference is that the bonding tool 200 has a shorter shaft 110′ which does not pass through the central opening formed on the rotary module 121. As shown in FIG. 2, the top portion of the shaft 110′ is coupled to a bottom portion of the rotary module 121 by the first linear bearing 124. It should be noted that the shape and length of the shaft 110, 110′ in the first and second embodiments are provided for illustrative purposes only, and are not intended to limit the scope of the invention. As long as a coupling is established between the shaft and the rotary module of the bonding tool so that the shaft is rotatable together with the rotary module and a connection means for providing vacuum to the shaft can be connected to the shaft, such an apparatus will fall within the scope of the invention.

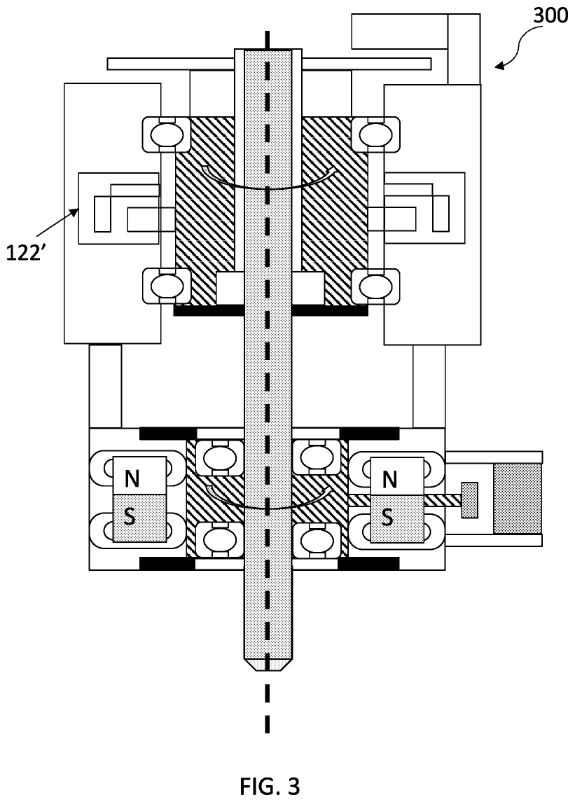

FIG. 3 is a schematic cross-sectional view of a bonding tool 300 according to a third embodiment of the invention. Compared with the first embodiment shown in FIG. 1A, the main difference is that the rotary motion actuator 122′ is in the form of a piezoelectric rotary motor. It should be noted that other types of rotary motors may also be used in various embodiments of the invention.

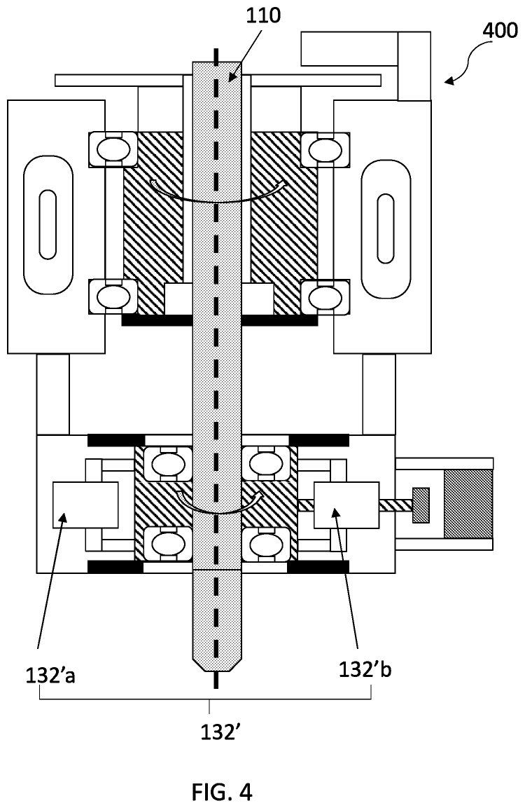

FIG. 4 is a schematic cross-sectional view of a bonding tool 400 according to a fourth embodiment of the invention. Compared with the first embodiment shown in FIG. 1A, the main difference is that the linear motion actuator 132′ is in the form of two piezoelectric linear motors 132′a, 132′b symmetrically arranged around the shaft 110. It should be noted that other types of linear motors may also be used in various embodiments of the invention.

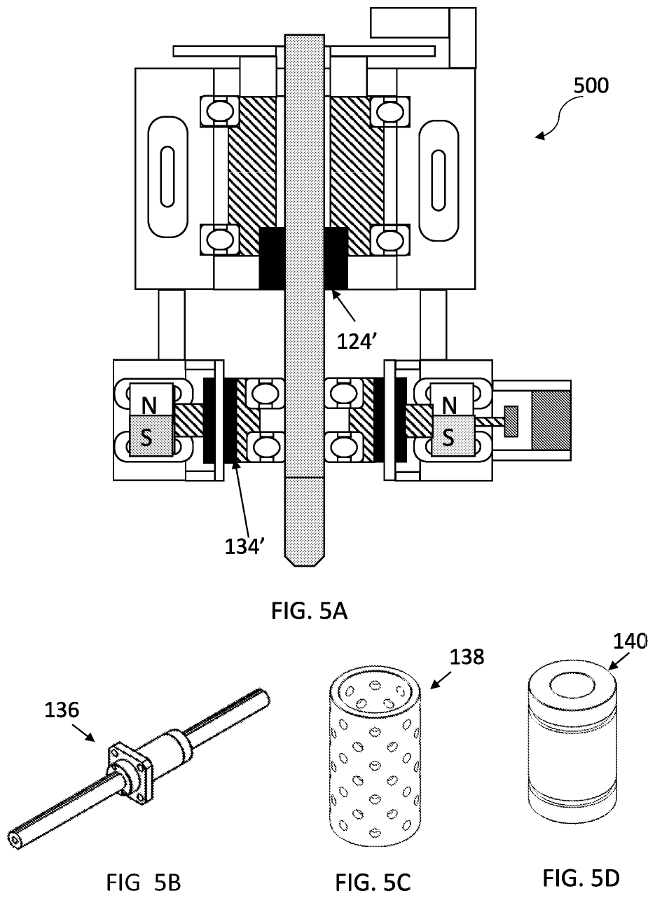

FIG. 5A is a schematic cross-sectional view of a bonding tool 500 according to a fifth embodiment of the invention. In this embodiment, the first linear bearing 124′ is in the form of a ball spine instead of a flexure, the second linear bearing 134′ may include a ball spine 136, a cage bearing 138 or a linear bush 140 as respectively shown in FIG. 5B-5D.

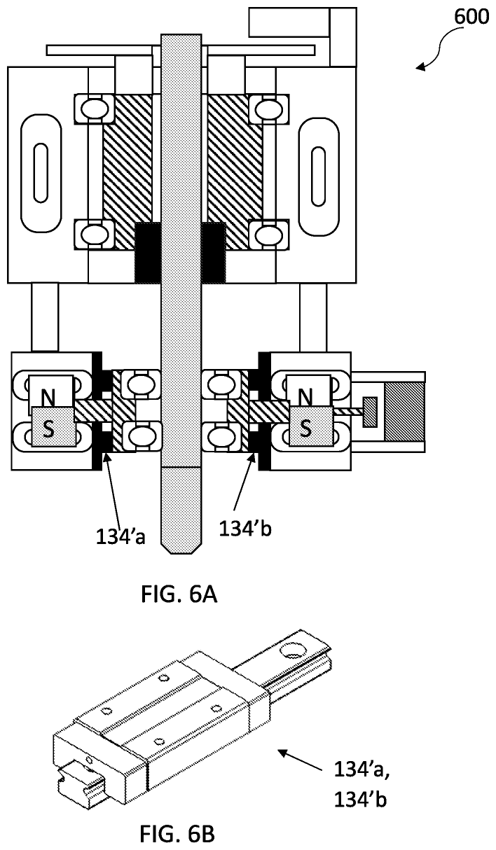

FIG. 6A is a schematic cross-sectional view of a bonding tool 600 according to a sixth embodiment of the invention. In this embodiment, the second linear bearing may include two linear motion guides 134′a, 134′b. FIG. 6B is a perspective view of a linear motion guide 134′a, 134′b according to the sixth embodiment.

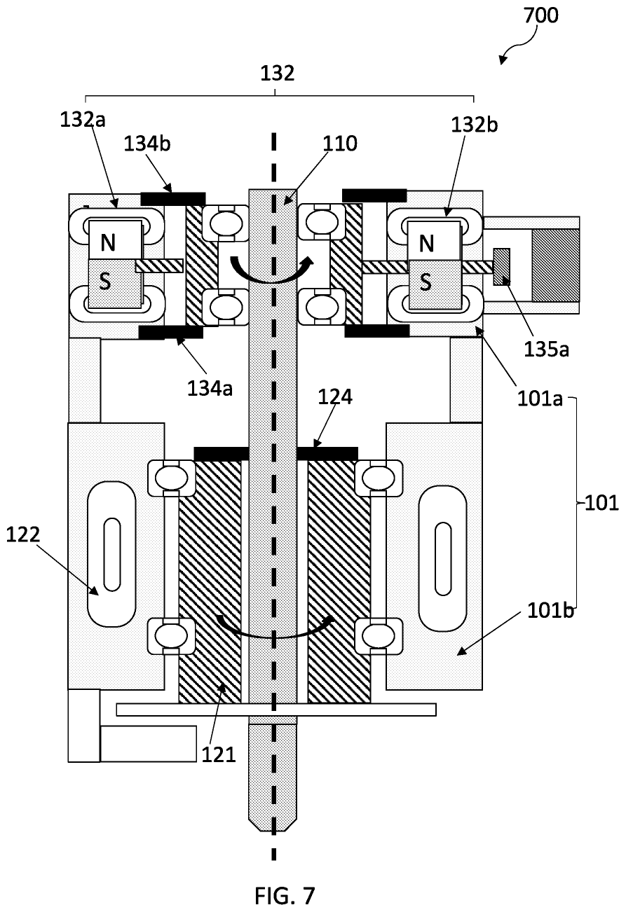

FIG. 7 is a schematic cross-sectional view of a bonding tool 700 according to a seventh embodiment of the invention. Compared with the first embodiment shown in FIG. 1A, in this embodiment, the rotary module 121 is coupled to a lower portion of the shaft 110 and the linear motion module 131 is coupled to an upper portion of the shaft 110. It should be noted that the shape and length of the shaft 110, the types of first and second linear bearings 124, 134a, 134b used in the bonding tool 700, the types of the rotary motion actuator 122 and linear motors 132a, 132b may vary according to other embodiments of the invention.

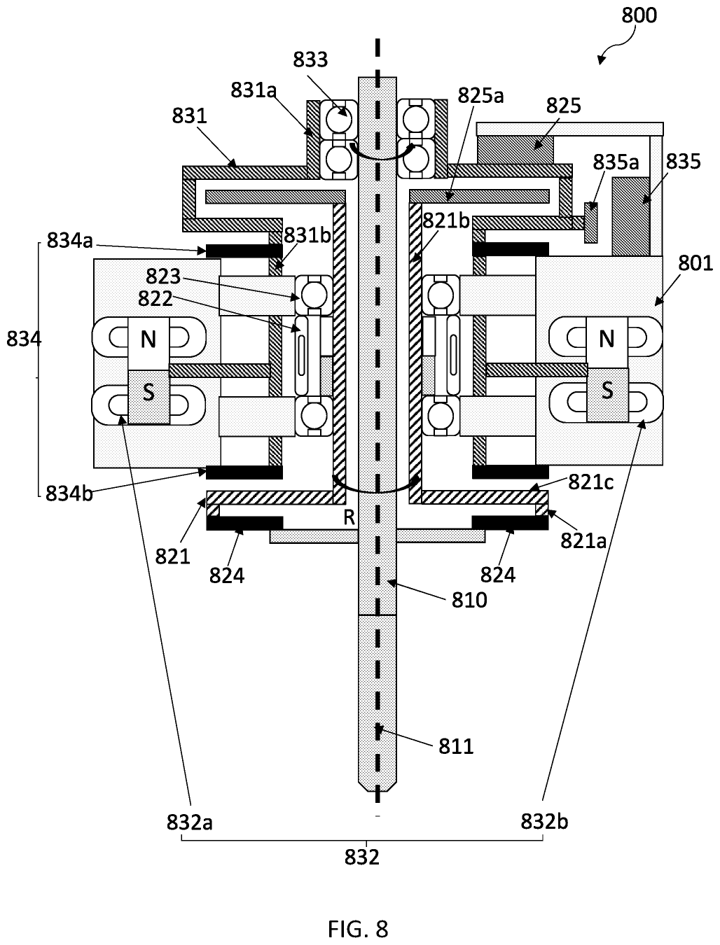

FIG. 8 is a schematic cross-sectional view of a bonding tool 800 according to an eighth embodiment of the invention. The bonding tool 800 includes a shaft 810, a rotary module 821, a rotary motion actuator 822, a linear motion module 831 and a linear motion actuator 832. In the first to seventh embodiments, the rotary module 121 and the linear motion module 131 are arranged respectively along upper or lower portions of the shaft 110. However, in the eighth embodiment, although the rotary module 821 and the linear motion module 831 are coupled to the shaft 810 at different positions or portions of the shaft 810, both the rotary module 821 and the linear motion module 831 are arranged along the upper and middle portions of the shaft 810. The purpose of this arrangement is to leave more available space around the lower portion of the shaft 810 to accommodate other modules for a bonding process so as to avoid possible interferences to the actual bonding process due to the space around the lower portion of the shaft 810 being occupied by some components of the bonding tool 800.

As shown in FIG. 8, the rotary module 821 includes a bottom coupling part 821a, a tubular structure 821b and a connecting part 821c located between the bottom coupling part 821a and the tubular structure 821b. The connecting part 821c extends horizontally from one end of the tubular structure 821b, and the bottom coupling part 821a is attached to a free end of the connecting part 821c. The coupling part 821a is coupled to a lower position R of the middle portion of the shaft 810 so that the shaft 810 is rotatable together with the rotary module 821. The rotary motion actuator 822 is operably connected to the tubular structure 821b of the rotary module 821 and operative to drive the rotary module 821 and the shaft 810 to rotate about a rotary axis 811 extending substantially along a central axis of the shaft 810. The rotary motion actuator 822 is in the form of an electromagnetic rotary motor in this embodiment. It should be noted that other types of rotary motors may be used in this embodiment to replace the electromagnetic rotary motor.

The linear motion module 831 includes a top coupling part 831a and a frame part 831b extending downwardly from the coupling part 831a. The top coupling part 831a is coupled to an upper portion of the shaft 810 so that the shaft 810 is movable with the linear motion module 831. The frame part 831b is arranged around the upper and middle portions of the shaft 810. A bottom end of the linear motion module 831 is located above the connecting part 821c of the rotary module 821. The linear motion actuator 832 includes two electromagnetic motors 832a, 832b which are operably connected to the frame part 831b of the linear motion module 831 and operative to drive the linear motion module 831 and the shaft 810 to move in directions parallel to the rotary axis 811. The two electromagnetic motors 832a, 832b are symmetrically around the shaft 810.

The bonding tool 800 further includes a first rotary bearing 823 coupled to an external surface of the tubular structure 821b of the rotary module 821 to guide the rotary module 821 to rotate about the rotary axis 811, and a second rotary bearing 833 coupled to the upper portion of the shaft 810 to guide the shaft 810 to rotate about the rotary axis 811. The top coupling part 831a is coupled to the upper portion of the shaft 810 through the second rotary bearing 833. The rotary bearings 823, 833 serve to reduce or avoid friction among different slidable components during the rotary motion of the bonding tool 800.

The bonding tool 800 further includes a first linear bearing 824 and a second linear bearing 834 in order to reduce or avoid friction among different components during the linear motion of the bonding tool 800. The first linear bearing 824 is configured to couple the bottom coupling part 821a of the rotary module 821 to the shaft 810 such that the rotary power generated from the rotary motion actuator 822 is transmitted to the shaft 810 such that the shaft 810 is driven to rotate together with the rotary module 821 about the rotary axis 811. The first linear bearing 824 may be in the form of a flexure. The second linear bearing 834 is coupled to the frame part 831b of the linear motion module 831 to guide the linear motion module 831 to move up and down parallel to the rotary axis 811. In this embodiment, the second linear bearing 834 includes a first flexure 834a coupled to an upper portion of the frame part 831b of the linear motion module 831 and a second flexure 834b coupled to a bottom portion of the linear motion module 831. The second linear bearing 834 is provided to guide the linear motion of the linear motion module 831. The second flexure 834b of the second linear bearing 834 is also provided to support the linear motion module 831.

The bonding tool 800 further includes an outer housing/frame 801 in which the rotary motion actuator 822 and the linear motion actuator 832 are fixedly installed. The outer housing 801 is not movable relative to other parts or components of the bonding tool 800.

Referring to FIG. 8, the bonding tool 800 further includes at least one linear encoder 835 to monitor the linear motion of the shaft 810. The linear encoder 835 is installed on the outer housing 801 and coupled to the linear motion module 831 by a linear scale 835a. The linear scale 835a of the linear encoder 835 is linearly movable with the linear motion module 831 for determining a linear position of the shaft 810.

The bonding tool 800 further includes at least one rotary encoder 825 to monitor the rotary motion of the shaft 810. The rotary encoder 825 is installed on the outer housing 801. A rotary encoder disc 125a of the rotary encoder is attached to the tubular structure 821b, e.g., the top end of the tubular structure 821b, and rotates together with the rotary module 821 so that the rotary encoder 825 can be used to record and determine a rotary position of the shaft 810.

In the first to eighth embodiments of the invention, the linear motion actuator 132, 132′, 832 includes two linear motors 132a, 132b; 132a′, 132b′; 832a, 832b which are symmetrically arranged around the shaft 110, 810. It should be noted that in other embodiments, the linear motion actuator may include more than two linear motors, e.g., three or four linear motors, which are symmetrically arranged around the shaft as long as the symmetrical arrangement of the plurality of linear motors can ensure the total linear actuation force applied to the linear motion module is substantially collinear with a center of gravity of all linear moving parts of the bonding tool and a functional point of the bonding tool so as to avoid any bending moment during the linear motion of the bonding tool.

As will be appreciated from the above description, various embodiments of the invention provide a bond arm incorporating a decoupling mechanism. This newly designed bond arm includes separate rotary and linear motion modules which are respectively actuated by direct driving motors so as to effectively decouple and control the rotary and linear motions of the bond arm. Further, non-contact type linear bearings, e.g., flexures, may be used in the bond arm to guide the linear motion of the linear motion module and the shaft, to avoid generating any friction between the flexures and other components. Hence, a more accurate and consistent bonding force will be exerted on the electronic components. In addition, the shaft of the bond arm will not experience bending stress due to any bending moment during the linear motion thereof, as the linear motion actuator and the linear moving components of the bond arm are symmetrically arranged around the shaft. Also, with this design, the moving mass carried during linear motion of the bond arm is minimized so that the bonding force produced by the bond arm can be more accurately delivered.

Although the present invention has been described in considerable detail with reference to certain embodiments, other embodiments are possible. Therefore, the spirit and scope of the appended claims should not be limited to the description of the embodiments contained herein.

1. A bonding tool comprising:
a shaft,
a rotary module coupled to a first portion of the shaft,
a rotary motion actuator operatively connected to the rotary module and operative to drive the rotary module and the shaft to rotate about a rotary axis extending substantially along a central axis of the shaft,
a linear motion module coupled to a second portion of the shaft separate from the first portion, and
a linear motion actuator operatively connected to the linear motion module and operative to drive the linear motion module and the shaft to move in directions parallel to the rotary axis.

2. The bonding tool according to claim 1, further comprising a first rotary bearing coupled to the rotary module to guide the rotary module to rotate about the rotary axis, and a second rotary bearing coupled to the second portion of the shaft to guide the shaft to rotate about the rotary axis.

3. The bonding tool according to claim 1, further comprising a first linear bearing coupled to the rotary module and the first portion of the shaft to guide the shaft to move in directions parallel to the rotary axis, and a second linear bearing coupled to the linear motion module to guide the linear motion module to move in directions parallel to the rotary axis.

4. The bonding tool according to claim 3, wherein the second linear bearing comprises at least a first flexure coupled to a first portion of the linear motion module and a second flexure coupled to a second portion of the linear motion module.

5. The bonding tool according to claim 4, wherein the first flexure is coupled to a top portion or an upper portion of the linear motion module and the second flexure is coupled to a bottom portion of the linear motion module.

6. The bonding tool according to claim 3, wherein the second linear bearing comprises a linear bush, a cage bearing or a ball spine, which is coupled to the linear motion module for guiding the linear motion module to move in directions parallel to the rotary axis.

7. The bonding tool according to claim 3, wherein the second linear bearing comprises two linear motion guides which are respectively coupled to two opposite sides of the linear motion module in order to guide the linear motion module to move in directions parallel to the rotary axis.

8. The bonding tool according to claim 1, wherein the first linear bearing comprises a flexure or a ball spine.

9. The bonding tool according to claim 1, wherein the linear motion actuator comprises at least two linear motors which are arranged symmetrically around the shaft such that a total linear actuation force applied to the linear motion module is substantially collinear with a center of gravity of all linear moving parts of the bonding tool and a functional point of the bonding tool.

10. The bonding tool according to claim 1, further comprising an outer housing in which the rotary motion actuator and the linear motion actuator are fixedly installed.

11. The bonding tool according to claim 9, wherein the outer housing includes a first housing portion and a second housing portion connected to each other, the first housing portion being configured for housing the rotary module, the rotary motion actuator and the first portion of the shaft, and the second housing portion being configured for housing the linear motion module, the linear motion actuator and the second portion of the shaft.

12. The bonding tool according to claim 9, further comprising a linear encoder installed on the outer housing and coupled to the linear motion module, a linear scale of the linear encoder being linearly movable with the linear motion module for determining a linear position of the shaft.
